(19) United States
(12) Patent Application Publication
(10) Pub. No.: US 2018/0033620 A1
(43) Pub. Date: Feb. 1, 2018

(54) ROOM TEMPERATURE METHOD FOR THE PRODUCTION OF ELECTROTECHNICAL THIN LAYERS, THE USE OF SAME, AND A THIN LAYER HEATING SYSTEM OBTAINED IN THIS MANNER

(71) Applicant: DYNAMIC SOLAR SYSTEMS AG, Frankfurt (DE)

(72) Inventors: Patrick LINDER, Lehrberg (DE); Daniel LINDER, Lehrberg (DE)

(73) Assignee: DYNAMIC SOLAR SYSTEMS AG, Frankfurt (DE)

(21) Appl. No.: 15/554,070

(22) PCT Filed: Feb. 26, 2016
(86) PCT No.: PCT/DE2016/100085

§ 371 Date: Aug. 28, 2017

(30) Foreign Application Priority Data
Feb. 26, 2015 (DE) 10 2015 102 801.8
Dec. 2, 2015 (DE) 10 2015 015 435.4

(51) Int. Cl. H01L 21/02; B32B 9/00; C23C 22/68; C23C 28/02; C23C 28/00; H01B 1/22; B32B 37/14

(52) U.S. Cl. CPC H01L 21/02496; H01L 21/02587; H01L 21/02628; H01B 1/22; B32B 9/007; B32B 37/14; C23C 28/023; C23C 28/44; C23C 22/68; B32B 2264/105; B32B 2264/108; B32B 2309/027; B32B 2309/105

(57) ABSTRACT

Electrotechnical thin layers which can be used as a heating resistor and/or substrate for conductive layers are produced, in established methods, at high prices and extremely slowly. This problem is solved by virtue of a redox-reactively-deposited base layer which contains graphite, is formed at room temperature and on which, in the same sense, a metal forms a micrometer-scale metal layer within minutes to a few seconds by means of a redox reaction, at room temperature and during the definitive curing process. The double layer made available in this manner is highly flexible, allows soldering on copper layers, and can be used particularly advantageously as a thin-layer heating system.

### TECHNICAL FIELD

The present invention can generally be assigned to the field of electrotechnical thin layers. The technical field is sensibly defined in DE 10 2015 102 801, in which the inventors were involved. Known measures, features and methods can be taken from this application and the prior art cited therein.

### DESCRIPTION OF THE PRIOR ART

The present invention relates to methods of producing electrotechnical thin layers, especially electrotechnical layer sequences, which are usable as conductor layers and can be utilized for contacting of thin-layer heaters.

The subject matter claimed in the present context has been discovered in the context of the production of a thin-layer heater.

It has been known since 1921 from DE 390 400 A that heating resistors can be produced as a mixture of waterglass, graphite and various salts by preparatory precipitation, spreading and drying. Correspondingly, DE 410 375 A teaches physical drying of such a layer, which is finally surface-conditioned with acid. A disadvantage in these established processes is that the process of drying the dispersion is purely physical and hence takes a very long time.

As an alternative, DE 839 396 B teaches encapsulating a heating wire in a quartz glass shell in order thus to obtain a durable thermal radiator. This design disadvantageously requires the incorporation of the wire in pure quartz glass by melting at high to very high temperatures. Alternative composite bodies as disclosed in DE 1 446 978 A also require high temperatures in order to produce a dense Si—SiC—C composite body as solid-state heating element. Alternative designs which, as described in DD 266 693 A1, arrange graphite and further additions as a loose bed between two electrodes also disadvantageously envisage a large-volume arrangement of suitable material pairs. DE 196 479 35 B4 also teaches application of a mixture of graphite, carbon and/or carbon fiber blended with waterglass in a thick layer between electrodes. This too harbours the disadvantage that the electrodes can be attacked by the aggressive waterglass and therefore have to be executed with sufficient thickness. By contrast with what has been described above, the present invention is different in that it is located in the sector of thin films.

DE 3 650 278 T2, which is correspondingly directed to a thin heating film, is much more relevant by comparison. However, this document again disadvantageously teaches the carbonization of a polymer film, which requires a large amount of energy, it being necessary to convert said film to a graphite film by conversion at 1800° C.

It was therefore an object of the present invention to overcome the disadvantages of the prior art and to provide a method and an electrotechnical thin layer in accordance with the method, which, in spite of industrial processing at room temperature and with large-area fabrication, can offer thin layers that are solid, stable, preferably usable as a heating layer, and nevertheless modifiable with sufficient conductivity in terms of their electrotechnical properties for thin-layer contact connection.

This object is achieved in accordance with the features of the independent claims. Advantageous embodiments will be apparent from the dependent claims and the description which follows.

### SUMMARY OF THE INVENTION

The invention provides a room temperature method of producing electrotechnical thin layers, by providing electrically conductive and/or semiconductive, inorganic agglomerates in a dispersion over an area and curing them to form a layer, characterized in that the curing is conducted at room temperature and the curing is accelerated by contacting with at least one reagent.

In a preferred embodiment, an electrotechnical base layer is provided here over an area via dispersion and cured to give a layer; in this method, a predominantly aqueous carbon suspension comprising at least microscale graphite with an amorphous carbon component and optionally up to 49% by weight of additions of related carbon polymorphs including soot, activated carbon, tar, conductive black, furnace black, carbon black, lamp black, ESD black, is admixed with at least one metal powder, which is no more than a microscale powder, of a base-soluble industrial metal comprising at least aluminum and/or iron. The suspension is then adjusted to a reactive pH greater than 7 and the metals are at least partly dissolved. The reductive layer thus produced is applied and subjected to preliminary curing at least to form a stabilizing marginal shell, wherein the suspension applied in a thin layer is cured at least by accompanying UV exposure.

Subsequently, for preferred production of a conductive electrotechnical thin layer, a fresh dispersion, having a low sulfuric acid content, of a metal, preferably copper, is provided on the reductive base layer and complete curing is conducted at room temperature, the curing being accelerated by the reductive deposition within 5 minutes with deposition of a metal layer in the micrometer range.

Advantageously, the electrotechnical thin layer sequence thus produced can be used as a solderable, printable metal layer, more preferably as a thin-layer heater.

More preferably, contacting of the double layer by established soldering processes allows application of helpful and/or necessary contacts and/or circuits, which enables a multitude of electrotechnical thin layer products at extremely low cost. With production costs in the range from 1 to 10 Euros per square meter for the double layer flexibly supported on film or paper, the invention offers considerable potential for creation of value in the advantageous double layer combination.

### DESCRIPTION OF THE INVENTION AND ADVANTAGEOUS FEATURES

The invention provides a room temperature method of producing electrotechnical thin layers, by providing electrically conductive and/or semiconductive, inorganic agglomerates in a dispersion over an area and curing them to form a layer, characterized in that
the curing is conducted at room temperature and
the curing is accelerated by contacting with at least one reagent.

The method is preferably characterized in that a PV layer sequence is formed.

The method is preferably characterized in that the at least one base layer applied is a layer comprising agglomerates of at least one chain-forming element, the chain-forming element being selected from the group consisting of boron, aluminum, gallium, indium, carbon, silicon, germanium, tin, lead, phosphorus, arsenic, antimony, sulfur, selenium, tellurium, bromine, iodine.

The method is preferably characterized in that the base layer is provided in the form of a predominantly aqueous suspension and is cured by accompanying reaction.

The method is preferably characterized in that the base layer is provided in the form of an aqueous suspension, adjusted to a reactive pH and applied and is subjected to at least preliminary curing at room temperature.

The method is preferably characterized in that the base layer is provided in the form of an aqueous carbon suspension comprising at least one type of the carbon polymorphs of soot, graphite, activated carbon, tar, conductive black, furnace black, carbon black, lamp black, ESD black, is adjusted to a reactive pH and is cured as an oxidative or reductive layer.

The method is preferably characterized in that the pH is adjusted by addition of at least one compound, the compound being selected from the group consisting of sodium hydroxide solution, potassium hydroxide solution, calcium hydroxide, barium hydroxide, ammonia, hydrochloric acid, sulfuric acid, nitric acid, hydrogen peroxide, phosphoric acid, ascorbic acid, citric acid, tartaric acid, carboxylic salts, carboxylic acids, amines, amino acids.

The method is preferably characterized in that the layer, prior to application, as a free-flowing mixture or solution, is admixed with at least one metal from the group consisting of Li, Na, K, Be, Mg, Ca, Sr, Ba, B, Al, Ga, In, Tl, Si, Ge, Sn, Pb, As, Sb, Se, Te, Ti, Zr, Cr, Mn, Fe, Co, Ni, Cu, Zn, Hg, Au, Ag, Pt, Pd, Cd, with at least partial dissolution of the metal at an appropriate pH setting.

The method is preferably characterized in that the base layer used is a layer in the form of a free-flowing mixture or solution, which is applied in a thin layer and finally cured by accompanying reaction, assisted by at least one measure, said at least one measure being selected from the group consisting of UV exposure, contacting with CO₂, contacting with acidic gases, contacting with basic gases, contacting with oxidative gases, contacting with reducing gases, contacting with acid chlorides, contacting with urea solutions, contacting with metal oxide dispersion, contacting with metal carbonyls, contacting with metal complexes, contacting with metal compounds, contacting with metal salts, contacting with water.

Preference is given to the room temperature method of producing electrotechnical thin layers, especially a base layer, in which electrically conductive and/or semiconductive, inorganic agglomerates in a dispersion are provided over an area and cured to form a layer, characterized in that
the curing is conducted at room temperature,
the curing is accelerated by contacting with at least one reagent,
the at least one base layer applied is a layer including agglomerates of at least one chain-forming element, the chain-forming element consisting of carbon, in which case
the base layer as a predominantly aqueous carbon suspension

comprising at least microscale graphite with an amorphous carbon component and optionally up to 49% of additions of soot, activated carbon, tar, conductive black, furnace black, carbon black, lamp black, ESD black,
is admixed with at least one metal powder, which is no more than a microscale powder, of a base-soluble metal, preferably of at least one metal from the group consisting of silicon, aluminum, gallium, indium, magnesium, calcium, barium, iron, cobalt, nickel, copper, zinc, more preferably silicon, aluminum and iron,
the suspension is adjusted to a reactive pH greater than 7 and applied as a reductive layer and is subjected to preliminary curing at least to form a stabilizing marginal shell, wherein
the suspension applied in a thin layer is cured at least by accompanying UV exposure.

The method is preferably characterized in that, at room temperature, for production of a conductive electrotechnical thin layer, an inorganic agglomerate in a dispersion is provided over an area and cured to form a layer, wherein
a dispersion of a metal or a metal compound
is provided on a reductive or oxidative base layer,
the curing is conducted at room temperature, wherein
the curing is accelerated by contacting with the at least one metal compound to deposit the metal or a metal oxide.

The method is preferably characterized in that a base layer is provided in the form of a basic reductive layer comprising carbon, silicon, aluminum and iron.

The method is preferably characterized in that the dispersion used is an aqueous, slightly acidic copper solution, preferably a fresh, slightly acidic copper sulfate solution, with deposition of a copper layer.

The method is preferably characterized in that a metal layer of thickness up to 100 micrometers, preferably 0.5 to 80 micrometers, more preferably 3±2.5 micrometers, is deposited within not more than 5 minutes, preferably 1 to 2 minutes, more preferably within 30 seconds.

The method is preferably characterized in that a copper layer of thickness at least 0.5 micrometer with a conductivity around 100 ohms per centimeter, preferably of 0.5 to 10 ohms per centimeter, more preferably of 2±1.5 ohms per centimeter, is deposited.

The method is preferably characterized in that a further electrotechnical layer is deposited or formed atop the copper layer.

The method is preferably characterized in that a cover layer is applied and cured in defined regions atop a base layer and then a metal layer is formed as electrode layer in the regions that are still exposed.

The method is preferably characterized in that a base layer is electrostatically charged in a preparatory measure, preferably electrostatically charged in frictional contact with a polymer layer, more preferably electrostatically charged in frictional contact with a nylon brush roll.

The method is preferably characterized in that the method is conducted in a printing machine.

Preference is given to use of an electrotechnical thin layer sequence obtained by the method of the invention, wherein the electrotechnical thin layer sequence is usable as solderable metal layer, conductor layer of an integrated circuit, resistance layer of a circuit, semiconductor layer, resistive sensor, capacitative sensor, moisture sensor, photoresist, sensor for oxidizing/reducing gases, capacitor, ferroelectrically active layer, diode, thin-layer resistance heater, transistor, field-effect transistor, bipolar transistor, quantitative photocell, photovoltaic layer sequence, touch sensor.

The thin layer sequence is preferably obtained by the method of the invention as an electrotechnical double layer, preferably thin-layer heater, having a cured basic reductive base layer atop an optional carrier, comprising
carbon in the form of graphite and optionally up to 49% of further carbon polymorphs and/or carbon products,
at least partly dissolved iron and/or aluminum of purity 96%, with 4% typical impurities such as silicon, boron, aluminum, phosphorus, magnesium, calcium, zinc,
cured waterglass,
metal silicates; and
   a metal layer reductively deposited thereon, preferably composed of copper, in which case
the metal layer has a metallic conductivity of 2.5±2.475 ohms per centimeter,
   and optionally, preferably in the case of copper layers,
the double layer has a diode Zener voltage preferably in the region of 2.7±1 volts,
the double layer has a capacitance preferably in the region of 40±39.98 microfarads, more preferably with up to 25% of the resistance across the double layer being purely of capacitative nature and making no contribution to the impedance at high frequency.

### BRIEF DESCRIPTION OF THE FIGURES

The figures illustrate, with reference to diagrams,

FIG. 1: an advantageous embodiment, shown in top view, of a preparatively reductively deposited and at least partly cured base layer;

FIG. 2: an advantageous embodiment, shown in top view, of a covering layer which prevents the formation of a metal layer in the dark-colored regions.

### DETAILED ELUCIDATION OF THE INVENTION WITH REFERENCE TO WORKING EXAMPLES

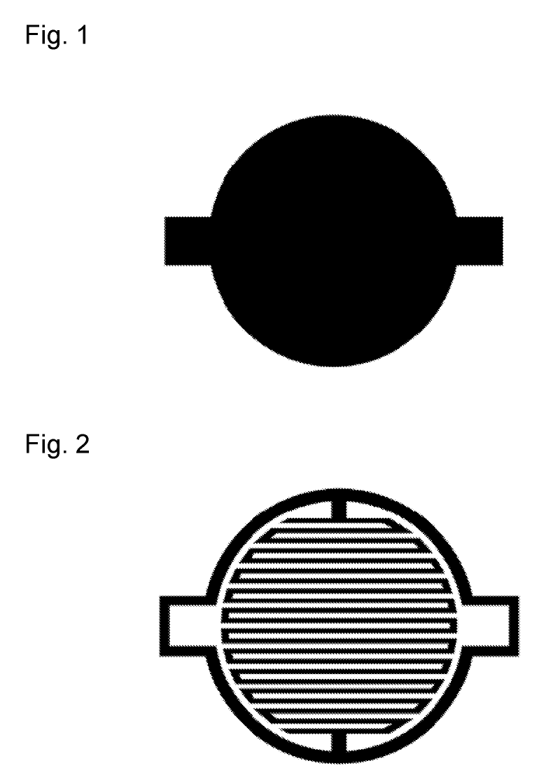

In an advantageous embodiment, and aqueous graphite dispersion was provided. In this dispersion, the microscale graphite contained a proportion of up to 49% of further carbon products such as amorphous graphite, activated carbon, conductive black, soot, lubricating graphite with oil residues/soot components and/or tar components. A microscale metal powder mixture of industrial aluminum and industrial iron was mixed into the aqueous graphite dispersion at around 50 percent by weight. The pH was adjusted to from 12 to 14 with partial dissolution of the metal powder, and the reacting mixture was homogenized in a cooled stirrer system, optionally adjusted in terms of flowability with silica, and printed onto a flexible paper sheet by means of a roll or screen system in predefined regions as illustrated in FIG. 1 and subjected to at least partial preliminary curing within up to 10 seconds—optionally with UV exposure. Pull-out characteristics, flowability and homogeneity can be adjusted via modifiers and auxiliaries such as emulsifiers, defoamers, thixotropic agents, basic buffer systems, adhesion promoters with siloxane copolymer, especially perpolymerized siloxane copolymers.

The base layer obtained, in the case of pure graphite, has conductivities in the range from mega- to teraohms per centimeter; additions of conductive black, optionally in combination with conductive metal oxides and/or established electrolytes, are able to lower the conductivity by several orders of magnitude to the kiloohm range. According to the planned use as an AC or DC heating layer, the resistance can be set at an extremely high level (for AC) or else at a low level (for DC). In each case, the layer that has been rendered reductive and basic is found to be usable advantageously as base layer for a metallically conductive layer. After application of a cover layer according to FIG. 2, in the regions outlined in white in FIG. 2, it is possible by contacting with a freshly produced copper solution with a low sulfuric acid content to generate a highly conductive metal layer of a few micrometers in thickness within seconds to minutes. The copper layer obtained in the form of globular agglomerates, after 30 seconds to a few minutes, has a thickness of micrometers, adheres firmly and durably on the base layer and has conductivities of 0.05 to 5 ohms per centimeter. Additional contacts and/or circuits can be applied to the finally dried and rinsed copper layer by conventional solder bonding. The inventors assume that the freshly reductive layer can be a reasonable explanation for the rapid copper-plating: by virtue of the graphite, the reducing conditions are stored in solid solution and can actively and effectively accelerate the copper-plating during the final curing. Copper layers in the micrometer range can thus be produced within seconds, which is otherwise possible only with deposition rates of micrometers per hour in alternative chemical methods.

### INDUSTRIAL APPLICABILITY

Electrotechnical thin layers usable as heating resistance and/or substrate for conductor layers are produced at high cost and extremely slowly in the established methods.

This problem is solved by a redox-reactively deposited, graphite-containing base layer formed at room temperature, on which a metal, by redox reaction, forms a metal layer on the micrometer scale within minutes or a few seconds in a corresponding manner at room temperature during the final curing.
The double layer thus obtainable is highly flexible, allows soldering to copper layers, and can be used particularly advantageously as a thin-layer heater.

1. A room temperature method of producing electrotechnical thin layers, by providing electrically conductive and/or semiconductive, inorganic agglomerates in a dispersion over an area and curing them to form a layer, characterized in that
the curing is conducted at room temperature and
the curing is accelerated by contacting with at least one reagent.

2. The method as claimed in claim 1, wherein a PV layer sequence is formed.

3. The method as claimed in claim 1, wherein the at least one base layer applied is a layer comprising agglomerates of at least one chain-forming element, the chain-forming element being selected from the group consisting of boron, aluminum, gallium, indium, carbon, silicon, germanium, tin, lead, phosphorus, arsenic, antimony, sulfur, selenium, tellurium, bromine, iodine.

4. The method as claimed in claim 3, wherein the base layer is provided in the form of a predominantly aqueous dispersion and is cured by accompanying reaction.

5. The method as claimed in claim 3, wherein the base layer is provided in the form of an aqueous suspension, adjusted to a reactive pH and applied and is subjected to at least preliminary curing at room temperature.

6. The method as claimed in claim 3, wherein the base layer is provided in the form of an aqueous carbon suspension comprising at least one type of the carbon polymorphs of soot, graphite, activated carbon, tar, conductive black, furnace black, carbon black, lamp black, ESD black, is adjusted to a reactive pH and is cured as an oxidative or reductive layer.

7. The method as claimed in claim 3, wherein the pH is adjusted by addition of at least one compound, the compound being selected from the group consisting of sodium hydroxide solution, potassium hydroxide solution, calcium hydroxide, barium hydroxide, ammonia, hydrochloric acid, sulfuric acid, nitric acid, hydrogen peroxide, phosphoric acid, ascorbic acid, citric acid, tartaric acid, carboxylic salts, carboxylic acids, amines, amino acids.

8. The method as claimed in claim 1, wherein the layer, prior to application, as a free-flowing mixture or solution, is admixed with at least one metal from the group consisting of Li, Na, K, Be, Mg, Ca, Sr, Ba, B, Al, Ga, In, Tl, Si, Ge, Sn, Pb, As, Sb, Se, Te, Ti, Zr, Cr, Mn, Fe, Co, Ni, Cu, Zn, Hg, Au, Ag, Pt, Pd, Cd, with at least partial dissolution of the metal at an appropriate pH setting.

9. The method as claimed in claim 1, wherein the base layer used is a layer in the form of a free-flowing mixture or solution, which is applied in a thin layer and finally cured by accompanying reaction, assisted by at least one measure, said at least one measure being selected from the group consisting of UV exposure, contacting with CO2, contacting with acidic gases, contacting with basic gases, contacting with oxidative gases, contacting with reducing gases, contacting with acid chlorides, contacting with urea solutions, contacting with metal oxide dispersion, contacting with metal carbonyls, contacting with metal complexes, contacting with metal compounds, contacting with metal salts, contacting with water.

10. A room temperature method of producing electrotechnical thin layers, especially a base layer, as claimed in claim 1, wherein electrically conductive and/or semiconductive, inorganic agglomerates in a dispersion are provided over an area and cured to form a layer, characterized in that
the curing is conducted at room temperature,
the curing is accelerated by contacting with at least one reagent,
the at least one base layer applied is a layer including agglomerates of at least one chain-forming element, the chain-forming element consisting of carbon, in which case
the base layer as a predominantly aqueous carbon suspension comprising at least microscale graphite with an amorphous carbon component and optionally up to 49% of additions of soot, activated carbon, tar, conductive black, furnace black, carbon black, lamp black, ESD black,
is admixed with at least one metal powder, which is no more than a microscale powder, of a base-soluble metal, preferably of at least one metal from the group consisting of silicon, aluminum, gallium, indium, magnesium, calcium, barium, iron, cobalt, nickel, copper, zinc, more preferably silicon, aluminum and iron,
the suspension is adjusted to a reactive pH greater than 7 and applied as a reductive layer and is subjected to preliminary curing at least to form a stabilizing marginal shell, wherein
the suspension applied in a thin layer is cured at least by accompanying UV exposure.

11. The method as claimed in claim 1, wherein, at room temperature, for production of a conductive electrotechnical thin layer, an inorganic agglomerate in a dispersion is provided over an area and cured to form a layer, characterized in that
a dispersion of a metal or a metal compound
is provided on a reductive or oxidative base layer,
the curing is conducted at room temperature, wherein
the curing is accelerated by contacting with the at least one metal compound to deposit the metal or a metal oxide.

12. The method as claimed in claim 11, wherein a base layer is provided in the form of a basic reductive layer comprising carbon, silicon, aluminum and iron.

13. The method as claimed in claim 11, wherein the dispersion used is an aqueous, slightly acidic copper solution, preferably a fresh, slightly acidic copper sulfate solution, with deposition of a copper layer.

14. The method as claimed in claim 11, wherein a metal layer of thickness up to 100 micrometers, preferably 0.5 to 80 micrometers, more preferably 3±2.5 micrometers, is deposited within not more than 5 minutes, preferably 1 to 2 minutes, more preferably within 30 seconds.

15. The method as claimed in claim 1, wherein a copper layer of thickness at least 0.5 micrometer with a conductivity around 100 ohms per centimeter, preferably of 0.5 to 10 ohms per centimeter, more preferably of 2±1.5 ohms per centimeter, is deposited.

16. The method as claimed in claim 15, wherein a further electrotechnical layer is deposited or formed atop the copper layer.

17. The method as claimed in claim 11, wherein a cover layer is applied and cured in defined regions atop a base layer and then a metal layer is formed as electrode layer in the regions that are still exposed.

18. The method as claimed in claim 1, wherein a base layer is electrostatically charged in a preparatory measure, preferably electrostatically charged in frictional contact with a polymer layer, more preferably electrostatically charged in frictional contact with a nylon brush roll.

19. The method as claimed in claim 11, wherein the method is conducted in a printing machine.

20. (canceled)

21. An electrotechnical double layer, preferably thin-layer heater, obtained according to claim 1, having
a cured basic reductive base layer atop an optional carrier, comprising
carbon in the form of graphite and optionally up to 49% of further carbon polymorphs and/or carbon products,
at least partly dissolved iron and/or aluminum of purity 96%, with 4% typical impurities such as silicon, boron, aluminum, phosphorus, magnesium, calcium, zinc,
cured waterglass,
metal silicates;
and
a metal layer reductively deposited thereon, preferably composed of copper, in which case
the metal layer has a metallic conductivity of 2.5±2.475 ohms per centimeter,
and optionally, preferably in the case of copper layers,
the double layer has a diode Zener voltage preferably in the region of 2.7 ±1 volts,
the double layer has a capacitance preferably in the region of 40±39.98 microfarads, more preferably with up to 25% of the resistance across the double layer being purely of capacitative nature and making no contribution to the impedance at high frequency.
